(19) United States
(12) Patent Application Publication
(10) Pub. No.: US 2025/0359319 A1
(43) Pub. Date: Nov. 20, 2025

(54) POWER GATING USING NANOELECTROMECHANICAL SYSTEMS (NEMS) IN BACK END OF LINE (BEOL)

(71) Applicant: Taiwan Semiconductor Manufacturing Company, Ltd., Hsin-Chu (TW)

(72) Inventors: Hung-Li Chiang, Taipei City (TW); Ching-Hui Lin, Taichung City (TW); Chun-Ren Cheng, Hsin-Chu City (TW); Iuliana Radu, Hsinchu County (TW)

(21) Appl. No.: 19/288,097

(22) Filed: Aug. 1, 2025

Related U.S. Application Data
(63) Continuation of application No. 18/512,452, filed on Nov. 17, 2023.
(60) Provisional application No. 63/519,022, filed on Aug. 11, 2023.

(51) Int. Cl. H10D 84/85; B82Y 15/00; H10D 30/01; H10D 62/13

(52) U.S. Cl. CPC H10D 84/853; B82Y 15/00; H10D 30/024; H10D 62/154; H10D 62/158; H10D 84/856

(57) ABSTRACT

One aspect of the present disclosure pertains to a device. The device includes a substrate, a logic circuit disposed on the substrate, and a nanoelectromechanical systems (NEMS) device electrically connected to the logic circuit and formed on the substrate. The NEMS device includes a first electrode electrically connected to the logic circuit, a second electrode electrically connected to a first power supply, a movable feature electrically connected to the second electrode, and a control electrode operable to move the movable feature relative to the first electrode.

### PRIORITY DATA

This is continuation application of U.S. patent application Ser. No. 18/512,452, filed Nov. 17, 2023, which claims the benefits to U.S. Provisional Application No. 63/519,022, filed Aug. 11, 2023, each of which is herein incorporated by reference in its entirety.

### BACKGROUND

The electronics industry has experienced an ever-increasing demand for smaller and faster electronic devices that are simultaneously able to support a greater number of increasingly complex and sophisticated functions. To meet these demands, there is a continuing trend in the integrated circuit (IC) industry to manufacture low-cost, high-performance, and low-power ICs. Thus far, these goals have been achieved in large part by reducing IC dimensions (for example, minimum IC feature size), thereby improving production efficiency and lowering associated costs. However, such scaling has also increased complexity of the IC manufacturing processes. Thus, realizing continued advances in IC devices and their performance requires similar advances in IC manufacturing processes and technology.

As technology nodes become smaller, issues with leakage power become more pronounced. Leakage power refers static power consumed while the circuit is inactive or idle. In a CMOS circuit, even when transistors are turned off, leakage power is dissipated as leakage current flow from input power to ground. One technique in reducing power leakage is with power gating. Power gating refers to turning off functional blocks of an IC when they are not being used or when they are in an inactive mode. Power gating may be implemented through one or more gating transistors that disconnect the path between power supply (VDD) and ground (VSS). These gating transistors may be n-type or p-type header transistors that gate the VDD rails or n-type or p-type footer transistors that gate the VSS rails.

However, the gating transistors take up additional footprint in front end of line (FEOL) portions of the IC. This means that they will compete for space with neighboring logic device components. Further, these gating transistors may still exhibit some leakage current in the off state. Even further, using n-type transistors may induce headroom loss (voltage drop) for the virtual VDD when the circuit path is turned on, while using p-type transistors means lower driving capability than that of the n-type transistors.

Therefore, although existing methods and structures for power gating have been generally adequate for their intended purposes, they have not been entirely satisfactory in every aspect.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for illustration purposes only. In fact, the dimensions of the various features may be arbitrarily increased or reduced for clarity of discussion. It is also emphasized that the figures appended illustrate only typical embodiments of this invention and are therefore not to be considered limiting in scope, for the invention may apply equally well to other embodiments. Further, the accompanying figures may implicitly describe features not explicitly described in the detailed description.

FIG. 1 illustrates a circuit schematic of a semiconductor structure having a nanoelectromechanical systems (NEMS) device for power gating, according to an embodiment of the present disclosure.

FIGS. 2A-2B illustrates a semiconductor structure having a NEMS device, according to various embodiments of the present disclosure.

FIG. 3A illustrates a semiconductor structure having a NEMS device over or between metal interconnect layers, according to an embodiment of the present disclosure.

FIG. 3B illustrates a semiconductor structure having a NEMS device on a backside of a substrate, according to an embodiment of the present disclosure.

FIG. 3C illustrates a semiconductor structure having a NEMS device as part of a 3DIC structure, according to an embodiment of the present disclosure.

FIGS. 4A-4B illustrates a piezoelectric NEMS device, according to various embodiments of the present disclosure.

FIG. 5 illustrates a semiconductor structure having a vertical NEMS device, according to an embodiment of the present disclosure.

FIG. 6 illustrates a semiconductor structure having an in-plane NEMS device, according to an embodiment of the present disclosure.

FIG. 7 illustrates a semiconductor structure having a comb structure NEMS device, according to an embodiment of the present disclosure.

FIG. 8 illustrates a flowchart of a method to form a semiconductor structure having a NEMS device for power gating, according to an embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Further, when a number or a range of numbers is described with “about,” “approximately,” “substantially,” and the like, the term is intended to encompass numbers that are within a reasonable range considering variations that inherently arise during manufacturing as understood by one of ordinary skill in the art. For example, the number or range of numbers encompasses a reasonable range including the number described, such as within +/−10% of the number described, based on known manufacturing tolerances associated with manufacturing a feature having a characteristic associated with the number. For example, a material layer having a thickness of “about 5 nm” can encompass a dimension range from 4.5 nm to 5.5 nm where manufacturing tolerances associated with depositing the material layer are known to be +/−10% by one of ordinary skill in the art. And when comparing a dimension or size of a feature to another feature, the phrases “substantially the same,” “essentially the same,” “of similar size,” and the like, can be understood to be within +/−10% between the compared features. Further, disclosed dimensions of the different features can implicitly disclose dimension ratios between the different features. Still further, the present disclosure may repeat reference numerals and/or letters in the various examples. This repetition is for the purpose of simplicity and clarity and does not in itself dictate a relationship between the various embodiments and/or configurations discussed.

The present disclosure relates to semiconductor structures having an integrated NEMS device for power gating control. The NEMS device controls when to turn on and turn off a supply voltage (VDD) to a functional circuit, such as a logic circuit or a memory circuit. The NEMS device includes an input terminal, an output terminal, and a control terminal. In an embodiment, when a control voltage is applied to the control terminal, the NEMS device is turned on, thereby allowing current to flow from the input terminal to the output terminal such that the supply voltage VDD is applied at the output terminal and to a functional circuit.

In various embodiments, the present disclosure describes incorporating the NEMS device in the back end of line (BEOL). Since the NEMS devices are formed in the BEOL, power gating footprint in the front end of line (FEOL) is eliminated. For example, transistor regions in FEOL previously reserved for forming power gating transistors are removed and replaced with additional functional devices. FEOL generally refers to portions of the circuit where functional devices such as logic devices are formed. The FEOL generally includes everything up to but not including metal interconnect layers. These regions may include the substrate, source/drain features, active regions, gate, and device-level contacts. BEOL generally refers to circuit regions outside of the FEOL. These regions may include the metal interconnect layers, backside of the substrate, or another wafer as part of a 3DIC structure. Besides eliminating FEOL footprint, the present disclosure offers other advantages in power gating. Since the NEMS devices do not need to be formed in the FEOL, it can be formed in various places in the BEOL, allowing flexibility. Further, by using NEMS devices, there is no headroom loss when the circuit path is turned on (no VDD voltage drop). Further, in the off state, the NEMS device is physically off due to the mechanical switching nature of the NEMS device, so there is no leakage current. Further, various types of NEMS devices are provided, where at low additional cost, they allow for process easiness and high CMOS logic compatibility. The various types of NEMS devices may include cantilever NEMS devices, piezoelectric NEMS devices, vertical NEMS devices, in-plane NEMS devices, and comb structure NEMS devices.

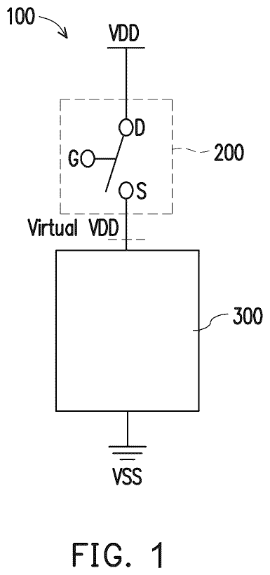

FIG. 1 illustrates a circuit schematic of a semiconductor structure 100 having a nanoelectromechanical systems (NEMS) device 200 for power gating, according to an embodiment of the present disclosure. The semiconductor structure 100 may include one or more semiconductor devices that form one or more circuit structures. As shown, the semiconductor structure 100 includes a NEMS device 200 electrically connected to a functional circuit such as a logic circuit 300. In another embodiment, the functional circuit may be a memory circuit. As shown, the NEMS device 200 acts as a switch. When the switch is turned on, power (e.g., supply voltage VDD) is supplied to the logic circuit 300. When the switch is turned off, power is not supplied to the logic circuit 300. Note that inside the logic circuit 300, there may also be transistor switches that switch on or off depending on if the logic circuit 300 is in operation. In any case, if the logic circuit is not being used or is in an idle state, the NEMS device physically cuts off supply voltage to the logic circuit.

Still referring to FIG. 1, the NEMS device 200 may be a three-terminal device that includes an input terminal D, a control terminal G, and an output terminal S. The input terminal D functionally represents a drain terminal, which is electrically connected to a power supply (e.g., supply voltage VDD). The control terminal G functionally represents a gate terminal, which is electrically connected to a control voltage (not shown). And the output terminal S functionally represents a source terminal, which is electrically connected to the logic circuit 300. The output terminal S corresponds to virtual power supply (e.g., virtual VDD), which supplies power to the logic circuits 300 depending on the operation of the NEMS device 200. The virtual power supply may supply voltage to a drain of a logic device in the logic circuit 300, and a source of a logic device in the logic circuit 300 may be electrically connected to ground (e.g., VSS).

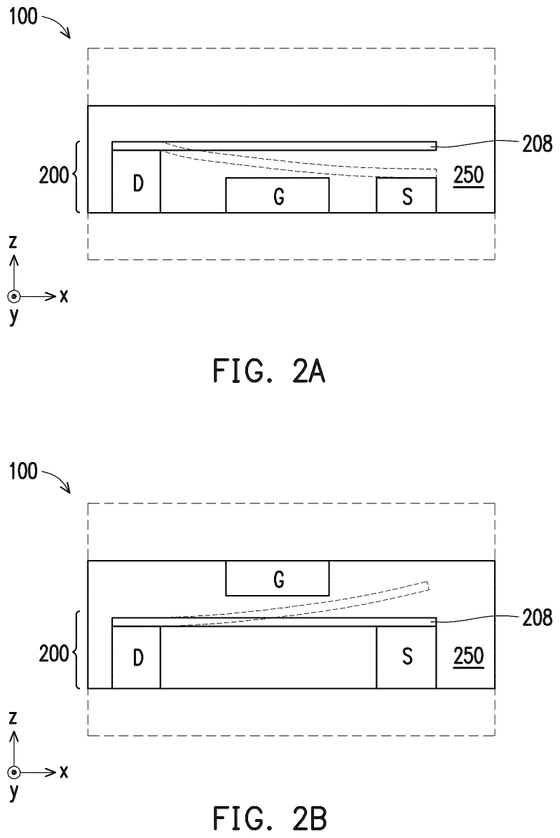

For ease of description, various electrodes that correspond to the input, control, and output terminals D, G, and S are similarly labeled in FIGS. 2A-7. The electrodes are similarly referred to as an input electrode D, a control electrode G, and an output electrode S. Note that the mechanics described in FIG. 1 may equally apply to the various semiconductor structures 100 in FIGS. 2A-7.

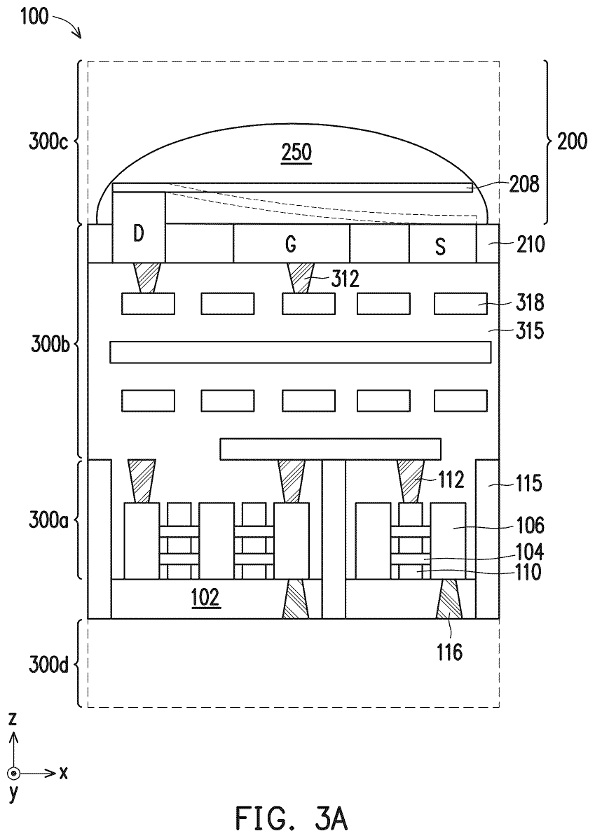

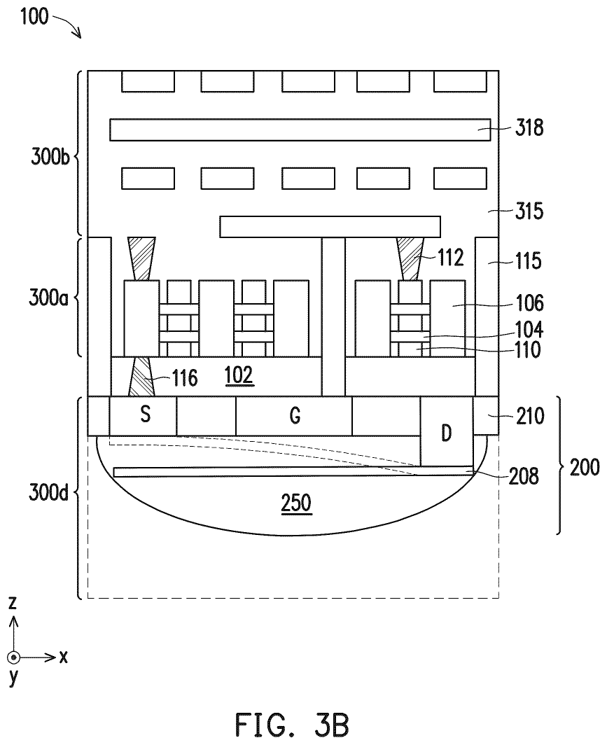

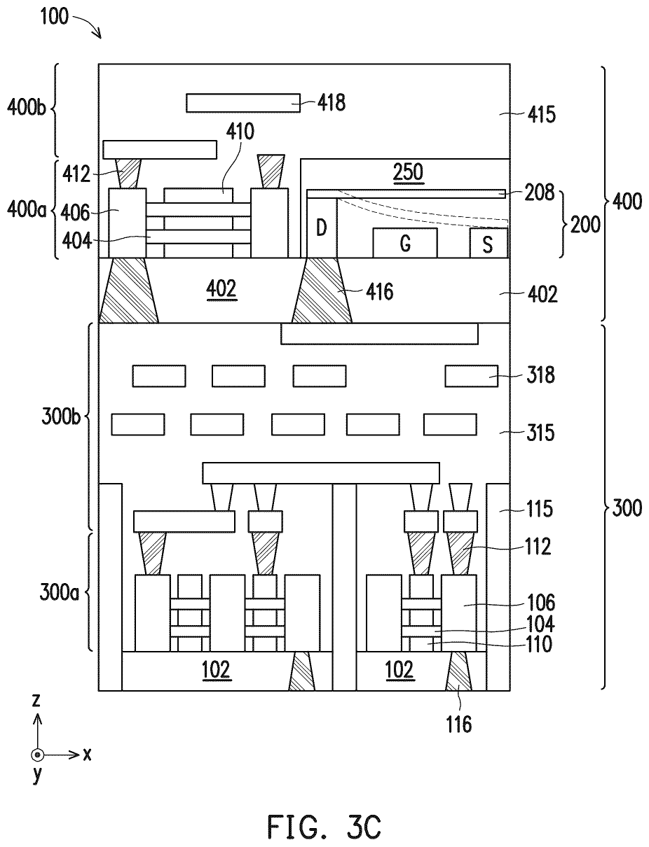

FIGS. 2A-2B illustrates a semiconductor structure 100 having a NEMS device 200, according to various embodiments of the present disclosure. FIGS. 2A-2B illustrates a cantilever NEMS device 200 having an input electrode D, a control electrode G, an output electrode S, and a movable feature 208 physically attached to the input electrode D. The cantilever NEMS device 200 is embedded in a larger semiconductor structure 100 as part of a BEOL process. The cantilever NEMS device 200 may be located in various BEOL locations, as described with respect to FIGS. 3A-3C. An air gap 250 surrounds the cantilever NEMS device 200 and allows a bendable end of the movable feature 208 to move freely (i.e., bend down or bend up). The bendable end may bend at a bending angle between 3 degrees to 20 degrees relative to a horizontal direction. In an embodiment, the bending angle is between about 5 degrees to about 15 degrees. Note that the range of the bending angle is not trivial. If the bending angle is too small, the bending end may not contact the output electrode S, and if the bending angle is too large, the movable feature 208 may inadvertently contact the control electrode G. In the present embodiment, the bendable end is at the output electrode S. Note that in other embodiments, the input electrode D and the output electrode S may be switched such that the movable feature 208 is physically attached to the output electrode S and the bendable end is at the input electrode D. In any case, when the movable feature electrically connects the input electrode D to the output electrode S, supply voltage at the input electrode D is equal to the virtual voltage VDD at the output electrode S, which then supplies power to the logic circuit 300. The input electrode D, the control electrode G, the output electrode S, and the movable feature may each include Cu, W, Pt, Ru, Al, Co, TaN, TiN, or a combination thereof.

Referring now to FIG. 2A, the cantilever NEMS device 200 is a normal-off device. In other words, when no control voltage is applied to the control electrode G, the movable feature 208 does not move and no power (i.e., supply voltage VDD) is supplied to the logic circuit 300. And when control voltage is applied to the control electrode G, the movable feature 208 bends such that the movable feature 208 contacts the output electrode S and power (i.e., supply voltage VDD) is supplied to the logic circuit 300. The movable feature 208 bends through electrostatic pull-in effect, where positive charges at the control electrode G attracts negative charges at the movable feature 208 (or vice versa). As shown, the movable feature has a movable end that bends down when control voltage is applied to the control electrode G. It may be desirable that the control voltage at the control electrode G be greater than the supply voltage VDD at the input electrode. This is so that the charge effect is dominated by the control voltage without being substantially affected by the supply voltage VDD. In an embodiment, the control voltage ranges between 2 volts to 10 volts, and the supply voltage VDD ranges between 0.6 volts to 1.2 volts. In the embodiment shown, the control electrode G and the output electrode S have coplanar (or substantially coplanar) top surfaces, and the input electrode D has a top surface above top surfaces of the control electrode G and the output electrode S. Further, the electrodes D, G, and S may have coplanar (or substantially coplanar) bottom surfaces.

Referring now to FIG. 2B, the cantilever NEMS device 200 is a normal-on device. In other words, when no control voltage is applied to the control electrode G, the movable feature 208 contacts the output electrode S and power (i.e., supply voltage VDD) is supplied to the logic circuit 300. And when control voltage is applied to the control electrode G, the movable feature 208 bends such that the movable feature 208 bends upwards to disconnect from the output electrode S and no power (i.e., supply voltage VDD) is supplied to the logic circuit 300. Like in FIG. 2A, the movable feature 208 bends through electrostatic pull-in effect, where positive charges at the control electrode G attracts negative charges at the movable feature 208 (or vice versa). As shown, the movable feature has a movable end that bends up when control voltage is applied to the control electrode G. Like in FIG. 2A, it may be desirable that the control voltage at the control electrode G be greater than the supply voltage VDD at the input electrode. This is so that the charge effect is dominated by the control voltage without being substantially affected by the supply voltage VDD. In an embodiment, the control voltage ranges between 2 volts to 10 volts, and the supply voltage VDD ranges between 0.6 volts to 1.2 volts. In the embodiment shown, the input electrode D and the output electrode S have coplanar (or substantially coplanar) top surfaces, and the control electrode G is above the top surfaces of the input electrode D and output electrode S. The control electrode G is also above the movable feature 208 for a normal-on device. Further, the electrodes D and S may have coplanar (or substantially coplanar) bottom surfaces.

FIGS. 3A-3C illustrates cantilever NEMS devices 200 in various BEOL locations of a semiconductor structure 100. FIGS. 3A-3C illustrates normal-off NEMS devices such as the one shown in FIG. 2A. However, in other embodiments, normal-on devices such as the one shown in FIG. 2B may be used.

Referring now to FIG. 3A, the NEMS device 200 may be formed in or above a metal interconnect structure 300b of a semiconductor structure 100. The semiconductor structure 100 includes a substrate 102, a logic circuit 300 over the substrate, and a NEMS device 200 electrically connected to the logic circuit 300 and formed on the substrate 102. The substrate 102 may be a silicon (Si) substrate, or a substrate having other semiconductor materials such as germanium (Ge), silicon carbide (SiC), silicon germanium (SiGe), or diamond. The logic circuit 300 includes logic devices 300a over the substrate 102, an interconnect structure 300b over the logic devices 300a, and a passivation structure 300c over the interconnect structure 300b. The logic circuit 300 may also include a backside interconnect structure 300d on a backside of the substrate 102. The backside interconnect structure 300d may electrically connect to the logic devices 300a through one or more through-substrate vias 116.

Still referring to FIG. 3A, the logic devices 300a are formed in a transistor region of the semiconductor structure 100 as part of a FEOL process. There may be one or more through-device vias 115 that penetrates through the transistor region and the substrate 102 for direct connection between the backside interconnect structure 300d and the interconnect structure 300b. In an embodiment, the logic devices 300a are functional devices for arithmetic, logic, controlling, and I/O operations. Each of the logic devices 300a may include a field effect transistor (FET) having a channel region 104 between source/drain (S/D) epitaxial features 106, a gate structure 110 over the channel region 104, S/D contacts 112 over the S/D epitaxial features, and a gate contact 112 over the gate structure. In the embodiment shown, the channel region 104 includes a stack of semiconductor channels wrapped around by the gate structure 110.

Still referring to FIG. 3A, the interconnect structure 300b is formed over the logic devices 300a. The interconnect structure 300b includes features that electrically couple various devices (for example, transistors, resistors, capacitors, and/or inductors) and/or components (for example, gate structures and/or source/drain features of the logic devices 300a), such that the various devices and/or components can operate as specified by design requirements. The interconnect structure 300b includes a combination of dielectric layers 315 such as interlayer dielectric (ILD) and/or intermetal dielectric (IMD) layers and electrically conductive layers. The conductive layers are configured to form vertical interconnect features, such as metal vias 312, and/or horizontal interconnect features, such as conductive metal lines 318. Vertical interconnect features typically connect horizontal interconnect features in different layers (or different planes) of the interconnect structure 300b. During operation, the interconnect structure 300b is configured to route signals between the logic devices 300a and/or the components of the logic devices 300a and/or distribute signals (for example, clock signals, voltage signals, and/or ground signals) to the logic devices 300a and/or the components of the logic devices.

Still referring to FIG. 3A, the NEMS device 200 is formed in or above the interconnect structure 300b. For example, the NEMS device 200 may be formed over a top metal line 318 of the interconnect structure 300b and landing on a top metal via 312 (as shown). For another example, the NEMS device 200 may be embedded and formed within the metal interconnect structure 300b, such as vertically between metal lines 318. The input, control, and output electrodes D, G, and S of the NEMS device 200 may be surrounded by a dielectric layer 210. As shown, the control electrode G and output electrode S have top surfaces coplanar (or substantially coplanar) with a top surface of the dielectric layer 210. And the top surface of the input electrode D protrudes above the top surface of the dielectric layer 210 and has a top portion exposed in an air gap 250. The air gap 250 surrounds the NEMS device 200 such that the movable feature 208 of the NEMS device 200 can freely bend to connect and disconnect from the output electrode S. The input electrode D is electrically connected to a power supply (e.g., supply voltage VDD), the control electrode G is electrically connected to a control voltage, and the output electrode S is electrically connected to the logic devices 300a through the interconnect structure 300b. The output electrode S is the VDD input to the logic devices 300a and acts as a virtual VDD.

Still referring to FIG. 3A, the passivation structure 300c is formed over the interconnect structure 300b. The passivation structure 300c may include redistribution layers and bonding pads surrounded by passivation layers. The redistribution layers and bonding pads may route electrical connections for package or die-level connections. Note that portions of the NEMS device 200 may be formed in the passivation structure 300c (as shown). In other embodiments, the NEMS device 200 may be wholly formed in the passivation structure 300c.

Still referring to FIG. 3A, the NEMS device 200 is disposed above and vertically separated from the logic devices 300a. In an embodiment, there may be 8 to 13 metal lines 318 between the NEMS device 200 and the logic devices 300a. In the present embodiment, when no control voltage is applied, the movable feature 208 of the NEMS device 200 does not touch the output electrode S and supply voltage VDD is disconnected from the logic devices 300a. When control voltage is applied to the control electrode G, the movable feature 208 of the NEMS device 200 bends and touches the output electrode S. Supply voltage VDD is then connected to the output electrode S and power is supplied to the logic devices 300a.

The dielectric layers described herein (e.g., dielectric layers 210 and 315) may include silicon oxide, a silicon oxide containing material, or a low-K dielectric layer such as TEOS oxide, undoped silicate glass (USG), or doped silicon oxide such as BPSG, FSG, PSG, BSG, and/or other suitable low-K dielectric material. Note that the dielectric layers 210 and 315 may each include multiple layers, but they are referred to as distinct layers for the sake of simplicity. One or more of the multiple layers may be a device-level interlayer dielectric (ILD) that embed and surround the logic devices 300a. The passivation layers described herein may include silicon oxide, silicon nitride, or a suitable dielectric material. In various examples, the various dielectric and passivation layers may be deposited by chemical vapor deposition (CVD), physical vapor deposition (PVD), atomic layer deposition (ALD), or combinations thereof.

Referring now to FIG. 3B, the NEMS device 200 may be formed on a backside of a substrate 102, according to an embodiment of the present disclosure. For example, the semiconductor structure 100 is flipped such that the substrate 102 is further processed from a backside. The processing may include forming a backside interconnect structure 300d having backside metal lines and vias (not shown). As part of forming the backside interconnect structure 300d, the NEMS device 200 may be formed on the backside of the substrate 102 opposite to the logic devices 300a. As shown, when the movable feature 208 bends up to contact the output electrode S, supply voltage at the input electrode D is supplied from a backside of the substrate 102 to the output electrode S. Then, the supply voltage at the output electrode S powers the logic devices 300a through one or more through-substrate vias 116. Note that one or more through-device vias 115 may electrically connect between the NEMS device 200 and the interconnect structure 300b (e.g., between control electrode G and a metal line 318 of the interconnect structure 300b). As such, control voltage may route from a frontside of the substrate 102 to the backside of the substrate via the through-device via 115. In other respects, the semiconductor structure in FIG. 3B may be similar to the semiconductor structure 100 in FIG. 3A.

Referring now to FIG. 3C, the NEMS device 200 may be formed as part of a 3DIC structure, according to an embodiment of the present disclosure. As shown, the semiconductor structure 100 is a 3D stacked semiconductor structure having two wafers or dies on top of each other. As shown, it is possible that the NEMS device 200 is formed in one wafer but electrically connects to a logic circuit formed in another wafer. In the embodiment shown, one wafer/die includes a logic circuit 300 having a substrate 102, logic devices 300a over the substrate 102, and an interconnect structure 300b over the logic devices 300a. The logic circuit 300 may be similar to what has been described in FIGS. 3A-3B. Another wafer/die includes a logic circuit 400 disposed over the logic circuit 300. The logic circuit 400 includes a substrate 402, logic devices 400a over the substrate 402, and an interconnect structure 400b over the logic devices 400a. Each of the logic devices 400a may include a field effect transistor (FET) having a channel region 404 between source/drain (S/D) epitaxial features 406, a gate structure 410 over the channel region 404, S/D contacts 412 over the S/D epitaxial features 406, and a gate contact (not shown) over the gate structure 410. In the embodiment shown, the channel region 404 includes a stack of semiconductor channels wrapped around by the gate structure 410. The interconnect structure 400b is connected to the logic devices 400a similar to how the interconnect structure 300b connects to the logic devices 300a (e.g., via metal lines 418). A dielectric layer 415 similar to the dielectric layer 315 may embed various features in the interconnect structure 400b and surrounding the logic devices 400a.

Still referring to FIG. 3C, the NEMS device 200 is formed as part of the logic circuit 400. As shown, the NEMS device 200 is directly above both the substrate 102 and the substrate 402. In an embodiment, supply voltage may be applied to the input electrode D through a through-substrate via 416. When a control voltage is applied to the control electrode G, the movable feature 208 bends within the air gap 250 to contact the output electrode S, and the output electrode S receives the supply voltage. In an embodiment, the output electrode S then supplies the supply voltage to logic devices 300a in the logic circuit 300 by routing through the interconnect structure 300b and other through-substrate vias 416 (not shown). In another embodiment, the output electrode S supplies the supply voltage to logic devices 400a in the logic circuit 400.

Although logic circuits 300 and 400 have been described with respect to FIGS. 3A-3C, the present disclosure is not limited thereto. In other embodiments, the NEMS device 200 may perform power gating on memory circuits having memory devices such as SRAM devices for storage and read/write operations.

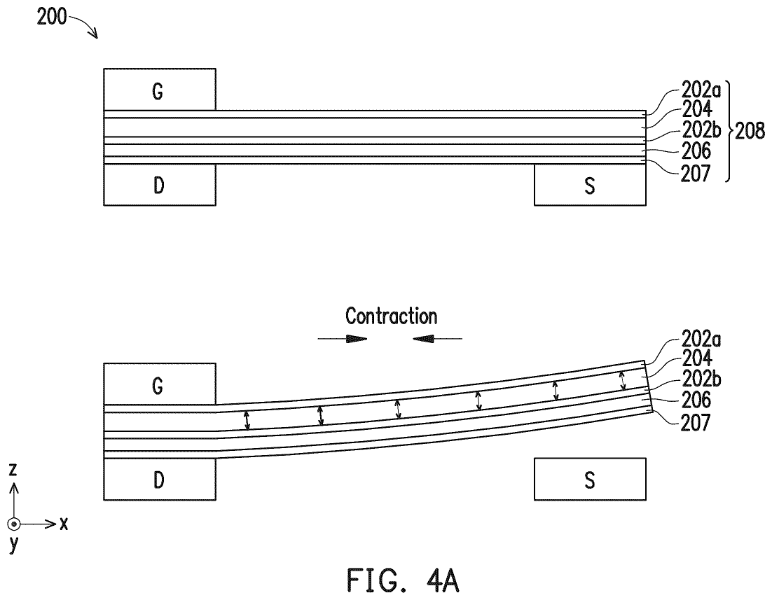

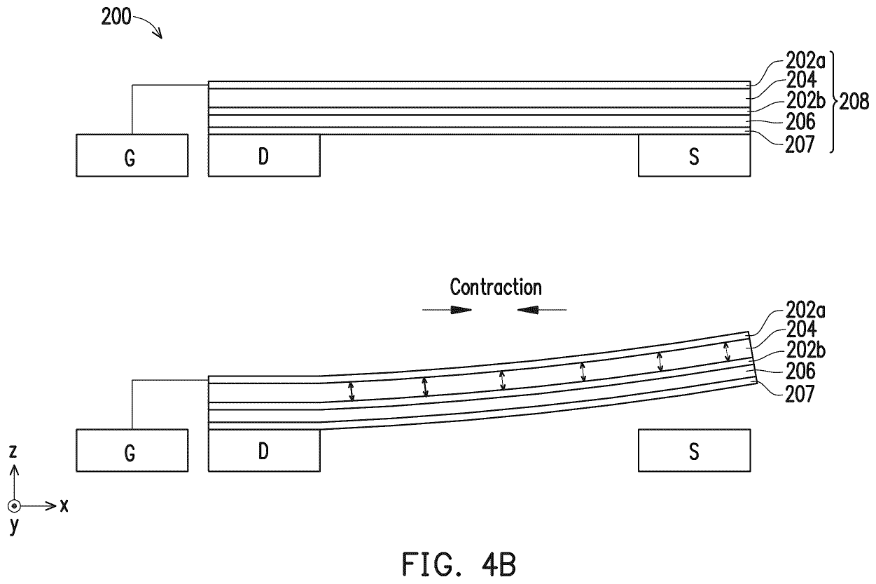

FIGS. 4A-4B illustrates a piezoelectric NEMS device 200, according to various embodiments of the present disclosure. The piezoelectric NEMS device 200 resembles the cantilever NEMS device 200 described in FIGS. 3A-3B and the piezoelectric NEMS device 200 may be similarly incorporated in the semiconductor structures 100 described in FIGS. 3A-3B. However, the piezoelectric NEMS device 200 has a different movement mechanism and it is configured differently from the cantilever NEMS device 200. Specifically, instead of bending through electrostatic pull-in effect, the bending in the piezoelectric NEMS device 200 is through contraction (or expansion) of the piezoelectric material. FIGS. 4A-4B illustrates normal-on devices but note that normal-off devices is also possible. For example, the piezoelectric NEMS device 200 is modified to have the bending direction and electrode height configurations shown in FIGS. 3A-3C.

Referring now to FIG. 4A, the piezoelectric NEMS device 200 includes an input electrode D, an output electrode S, a movable feature 208 over the input and output electrodes D and S, and a control electrode over the movable feature 208. The movable feature 208 has a fixed end attached to the input electrode D and a movable end over the output electrode. The movable end is operable to bend up or down depending on the control voltage applied. The control electrode G directly lands on a top surface of the movable feature 208. The input electrode D, the output electrode S, and the control electrode G may each include Cu, W, Pt, Ru, Al, Co, TaN, TiN, or a combination thereof.

Still referring to FIG. 4A, the movable feature 208 includes a conducting metal layer 207 landing on the input electrode D and landing on the output electrode S (when device is on), an insulator layer 206 landing on the conducting metal layer 207, a bottom piezoelectric electrode 202b landing on the insulator layer, a piezoelectric layer 204 landing on the bottom piezoelectric electrode 202b, and a top piezoelectric electrode 202a landing on the piezoelectric layer 204. The control electrode G then lands on the top piezoelectric electrode 202a. In the present embodiment, the control electrode G is directly opposite the input electrode D at the fixed end of the movable feature 208. If the control electrode G is not at the fixed end, it may move around during NEMS operation and causing reliability issues. In an embodiment, the conducting metal layer 207 includes Cu, W, Pt, Ru, Al, Co, TaN, TiN, or a combination thereof. In an embodiment, the insulator layer 206 includes SiO2, Si3N4, SiOC, SiCN, SiON, SiCON, or a combination thereof. In an embodiment, the bottom and top piezoelectric electrodes 202b and 202a include Cu, W, Pt, Ru, Al, Co, TaN, TiN, or a combination thereof. In an embodiment, the piezoelectric layer 204 includes BaTiO3, PbTiO3, Pb(ZrTi)O3, or a combination thereof.

The piezoelectric NEMS device 200 operates through a supply voltage at the input electrode D and a control voltage at the control electrode G. The two different voltages are insulated from each other by the insulating layer 206. When no control voltage is applied, the movable feature 208 is at rest, and the supply voltage at the input electrode D is supplied to the output electrode S through the conducting metal layer 207. When control voltage is applied, the bendable end of the movable feature 208 bends up and disconnects from the output electrode S. As such, the supply voltage is cut off from the output electrode. The movable feature 208 bends due to contraction of the piezoelectric layer 204. In the present embodiment, control voltage is applied to the top piezoelectric electrode 202a, and the bottom piezoelectric electrode 202b is connected to ground, thereby biasing the piezoelectric layer 204. As a result, the piezoelectric layer 204 may expand in the vertical direction due to the electric field, thereby causing contraction in the horizontal direction. The contraction then causes the bending up of the movable feature 208. The direction of bending may be controlled by the thickness of the piezoelectric layer 204 relative to the thickness of the insulating layer 206 and the conducting metal layer 207. For example, when the piezoelectric layer 204 is thicker than the combined thickness of the insulating layer 206 and the conducting metal layer 207, the movable feature bends up (as shown). For another example, when the piezoelectric layer 204 is thinner than the combined thickness of the insulating layer 206 and the conducting metal layer 207, the movable feature bends down. Other ways to control the direction of bending may include reversing polarity of the electric field such that the piezoelectric layer 204 may shrink in the vertical direction, thereby causing expansion in the horizontal direction.

Still referring to FIG. 4A, the control voltage may range between 2 volts to 10 volts, and the supply voltage may range between 0.6 volts to 1.2 volts. In an embodiment, the supply voltage is less than the control voltage (e.g., less than 2 volts). The length of the movable feature 208 may be between 200 nm to 1000 nm in the x direction. The thickness of the movable feature 208 may be between 75 nm to about 250 nm in the z direction. In an embodiment, the top and bottom piezoelectric electrodes 202a and 202b has a thickness ranging between about 5 nm to about 30 nm. In an embodiment, the piezoelectric layer 204 has a thickness ranging between about 50 nm to about 100 nm. In an embodiment, the insulator layer 206 has a thickness ranging between about 10 nm to about 50 nm. In an embodiment, the conducting metal layer 207 has a thickness ranging between about 10 nm to about 40 nm. The bendable end of the movable feature 208 may bend at a bending angle between 3 degrees to 20 degrees relative to a horizontal direction. In an embodiment, the bending angle is between about 5 degrees to about 15 degrees. Note that the range of the bending angle is not trivial. If the bending angle is too small, the bending end may not properly disconnect from the output electrode S, and if the bending angle is too large, the movable feature 208 may inadvertently contact other features in the semiconductor structure 100.

FIG. 4B illustrates a piezoelectric NEMS device 200 similar to that of FIG. 4A. The similar features will not be repeated again for the sake of brevity. The difference is in the location of the control electrode G. In FIG. 4A, the control electrode G lands on top of the movable feature 208. Here, the control electrode G may be formed in a same layer as the input and output electrodes D and S. The control electrode G is then electrically routed to the top piezoelectric electrode 202a through metal routings such as metal vias and interconnects.

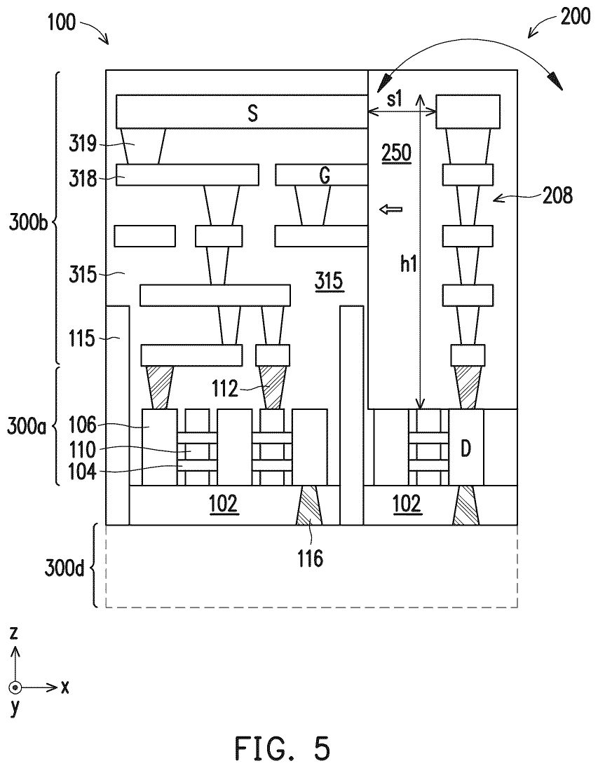

FIG. 5 illustrates a semiconductor structure 100 having a vertical NEMS device 200, according to an embodiment of the present disclosure. The semiconductor structure 100 includes similar features as those described with respect to FIGS. 3A-3C. The similar features will not be repeated again for the sake of brevity. The difference is in how the vertical NEMS device 200 is oriented and configured. As shown, the vertical NEMS device 200 includes an input electrode D, a control electrode G, an output electrode S, and a movable feature 208 physically attached to the input electrode D. The input electrode D, the control electrode G, the output electrode S, and the movable feature 208 may each include Cu, W, Pt, Ru, Al, Co, TaN, TiN, or a combination thereof. The input electrode D may be disposed adjacent to the logic devices 300a. In an embodiment, the input electrode D may land on (or electrically connect to) an S/D epitaxial feature of a transistor device separate from the logic devices 300a. In this way, the separate transistor device is not power gated and is always connected to a power supply, and only the logic devices 300a are. The output electrode S is directly above and landing on a metal via 319 of the interconnect structure 300b. In an embodiment, the output electrode S may be a metal line 318 of the interconnect structure 300b. Although not shown, there may be additional metal lines 318 over the output electrode S. The control electrode G is disposed above the logic devices 300a and under the output electrode S. In an embodiment, the control electrode G may be another metal line 318 of the interconnect structure 300b. Each of the input electrode D, output electrode S, and control electrode G are embedded in a dielectric layer (e.g., dielectric layer 315). The movable feature 208 is exposed and surrounded by an air gap 250, which allows the movable feature 208 to move freely (i.e., bend in the x direction along the x-z plane). The movable feature 208 may bend at a bending angle between 3 degrees to 20 degrees relative to a vertical direction (z direction). In an embodiment, the bending angle is between about 5 degrees to about 15 degrees. As shown, the movable feature 208 may be a vertical metal pillar (or beam) having multiple metal lines connected by metal vias. The movable feature 208 may have a height h1 in the z direction and is distanced away from the output electrode S by a spacing s1 in the x direction. In an embodiment, the height h1 is in a range between about 200 nm to about 1000 nm, such as between 200 nm to 500 nm. In an embodiment, the spacing s1 is in a range between about 10 nm to about 200 nm, such as between 20 nm to 100 nm. In any case, to ensure contact between the movable feature 208 and the output electrode S, a tangent of the bending angle is equal to a ratio of the spacing s1 to the height h1.

Like the cantilever NEMS device 200 described in FIGS. 3A-3B, the vertical NEMS device 200 operates through electrostatic pull-in effect. FIG. 5 shows a normal-off device, however in other embodiments, the vertical NEMS device 200 may be a normal-on device. As shown here, when no control voltage is applied to the control electrode G, the movable feature is at rest, and supply voltage at the input electrode D is disconnected from the output electrode S. When control voltage is applied to the control electrode G, the movable feature 208 bends towards the control electrode G until the movable feature 208 contacts the output electrode S. The movable feature 208 may bend through electrostatic pull-in effect, where positive charges at the control electrode G attracts negative charges at the movable feature 208 (or vice versa), and the movable feature bends towards the control electrode G. It may be desirable that the control voltage at the control electrode G be greater than the supply voltage at the input electrode. This is so that the charge effect is dominated by the control voltage without being substantially affected by the supply voltage. In an embodiment, the control voltage ranges between 2 volts to 10 volts, and the supply voltage VDD ranges between 0.6 volts to 1.2 volts.

Still referring to FIG. 5, the movable feature directly lands on a top surface of the input electrode D. As the vertical NEMS device 200 bends over time, stress may accumulate at the base of the movable feature 208. In some embodiments, to maintain structural integrity and prevent breakage, the movable feature 208 may partially penetrate into the input electrode D for structural support.

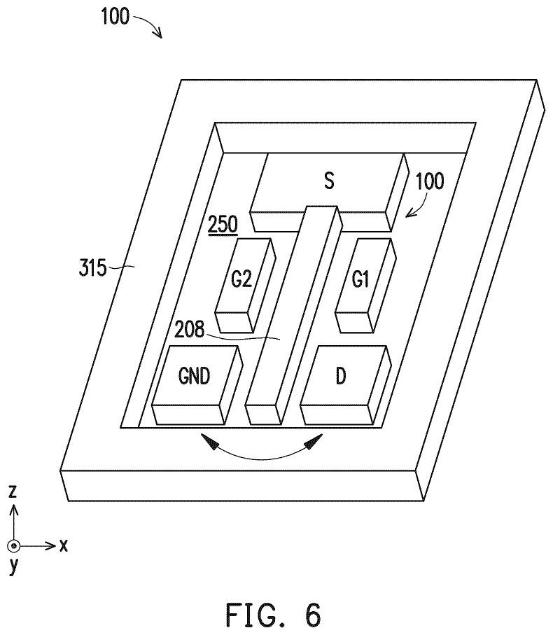

FIG. 6 illustrates a semiconductor structure 100 having an in-plane NEMS device 200, according to an embodiment of the present disclosure. As shown, the in-plane NEMS device 200 includes a movable feature 208 that bends in the x-y plane (as opposed to the x-z plane as shown in FIG. 5). The in-plane NEMS device 200 may be embedded in a dielectric layer 315 and exposed in an air gap 250. The in-plane NEMS device 200 may be disposed over logic devices 400a in the logic circuit 400. In the embodiment shown, the in-plane NEMS device 200 includes an input electrode D, a first control electrode G1, an output electrode S, a movable feature 208 extending from the output electrode S, a second control electrode G2, and a ground electrode GND. Each of these electrodes and the movable feature 208 may include Cu, W, Pt, Ru, Al, Co, TaN, TiN, or a combination thereof. Each of these electrodes and the movable feature 208 may have substantially coplanar top and bottom surfaces as they are formed within a same layer of the semiconductor structure 100. The same layer may be a layer of an interconnect structure 300b over logic devices 300a, where additional interconnect layers may be formed thereon. The same layer may range between about 50 nm to about 150 nm. The length of the movable feature 208 may be between 200 nm to 1000 nm in the y direction, such as between about 200 nm to about 500 nm.

As shown, the in-plane NEMS device 200 may be a five terminal device. The first control electrode G1 controls the bending towards input electrode D. And the second control electrode G2 controls the bending towards the ground electrode GND. As shown, by applying separate control voltages to the first control electrode G1 or the second control electrode G2, the output electrode S either electrically connects to a supply voltage or to ground. By having the additional option to ground the output electrode S, performance of the logic devices 300a may be improved. The movable feature 208 may bend through electrostatic pull-in effect, where positive charges at the control electrodes G1/G2 attracts negative charges at the movable feature 208 (or vice versa), and the movable feature bends towards the control electrodes G1/G2. It may be desirable that the control voltage at the control electrode G be greater than the supply voltage at the input electrode. This is so that the charge effect is dominated by the control voltage without being substantially affected by the supply voltage. In an embodiment, the control voltage for the first and the second control electrode G1 and G2 ranges between 2 volts to 10 volts, and the supply voltage VDD ranges between 0.6 volts to 1.2 volts. The movable feature 208 may bend at a bending angle between 3 degrees to 20 degrees relative to a horizontal direction. In an embodiment, the bending angle is between about 5 degrees to about 15 degrees. Although FIG. 6 shows a 5 terminal device, the present disclosure is not limited thereto. For example, the control gate electrode G2 and the ground electrode GND may be removed to form a 3 terminal device. The 3 terminal device includes the input electrode D, the first control electrode G1, and the output electrode S. In this way, when the movable feature 208 disconnects from the input electrode D, the output electrode S is floating instead of grounded.

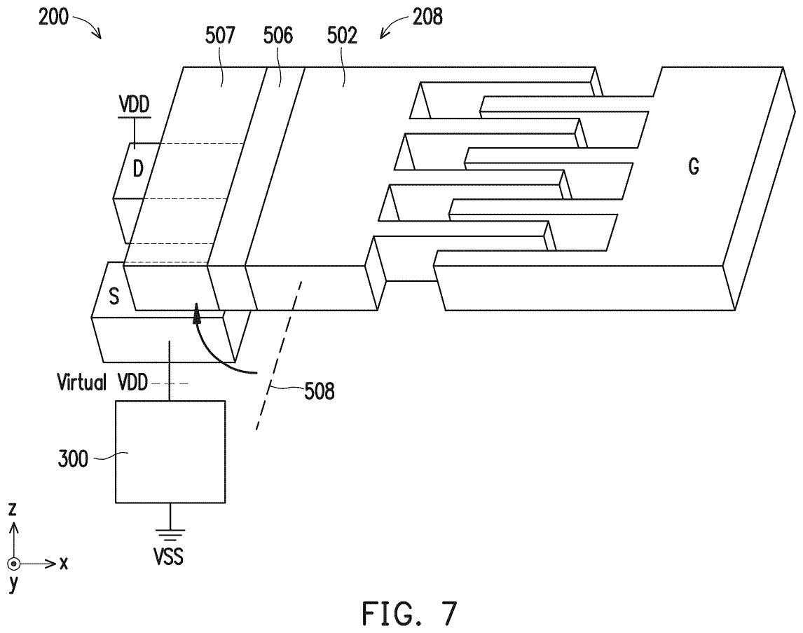

FIG. 7 illustrates a semiconductor structure 100 having a comb structure NEMS device 200, according to an embodiment of the present disclosure. The comb structure NEMS device 200 has an input electrode D, a control electrode G, an output electrode S, and a movable feature 208. The movable feature 208 is coupled to the control electrode G through a NEMS body 502 having a first set of conductive combs. The first set of conductive combs are capacitively coupled to a second set of conductive combs extending from the control electrode G. Each of the conductive combs may have a comb width ranging between about 5 nm to about 20 nm, and a comb length of about 50 nm to about 200 nm. There may be a gap width of about 10 nm between conductive combs. With more overlap area between the conductive combs, the switching time of the NEMS device may be reduced. As shown, the movable feature 208 further includes an insulator layer 506 and a metal layer 507, where the insulator layer 506 insulates the metal layer 507 from the NEMS body 502. The insulator layer 506 includes SiO2, Si3N4, SiOC, SiCN, SiON, SiCON, or a combination thereof. The metal layer 507 includes Cu, W, Pt, Ru, Al, Co, TaN, TiN, or a combination thereof. The control electrode G and the NEMS body 502 of the movable feature 208 may include silicon doped with phosphorous. In other embodiments, the control electrode G and the NEMS body 502 may include similar materials as the metal layer 507.

Like the cantilever NEMS device 200 described in FIGS. 3A-3B, the comb structure NEMS device 200 operates through electrostatic pull-in effect. FIG. 7 shows a normal-on device, however in other embodiments, the comb structure NEMS device 200 may be a normal-off device. The movable feature 208 is designed with a fixed portion functioning as a rotation axis 508 and is able to rotate around the rotation axis 508. Especially, the rotation axis 508 is configured such that the movable feature 208 rests at a level higher than that of the control gate G. In the disclosed embodiment, the rotation axis 508 is configured in the NEMS body 502. As shown here, when no control voltage is applied to the control electrode G, the metal layer 507 rests on the input electrode D and the output electrode S, and therefore electrically connects the input electrode D to the output electrode S and power (i.e., supply voltage VDD) is supplied to the logic circuit 300. And when control voltage is applied to the control electrode G, the movable feature 208 rotates such that the MEMS body 502 of the movable feature 208 moves down toward the second set of conductive combs extending from the control electrode G while the metal layer 507 of the movable feature 208 moves upwards to disconnect the output electrode S from the input electrode D and no power (i.e., supply voltage VDD) is supplied to the logic circuit 300. The movable feature 208 may rotates through electrostatic pull-in effect, where positive charges attract negative charges at the interdigitated conductive combs, thereby causing the movable feature 208 to move. In an embodiment, the movable feature 208 is designed with a rotation angle ranging between 3 degrees to 20 degrees relative to a horizontal direction. In an embodiment, the rotation angle is between about 5 degrees to about 15 degrees. Note that the range of the rotation angle is not trivial. If the rotation angle is too small, the bending end may not properly disconnect from the output electrode S, and if the rotation angle is too large, the movable feature 208 may inadvertently contact other features in the semiconductor structure 100. In an embodiment, the max movement of the movable feature 208 is 20 nm in the vertical direction. Like in FIG. 2A, it may be desirable that the control voltage at the control electrode G be greater than the supply voltage VDD at the input electrode. This is so that the charge effect is dominated by the control voltage without being substantially affected by the supply voltage VDD. In an embodiment, the control voltage ranges between 2 volts to 10 volts, and the supply voltage VDD ranges between 0.6 volts to 1.2 volts. In the embodiment shown, the input electrode D and the output electrode S have coplanar (or substantially coplanar) top surfaces, and the control electrode G is above the top surfaces of the input electrode D and output electrode S. Further, the electrodes D and S may have coplanar (or substantially coplanar) bottom surfaces. The comb structure NEMS device 200 may be designed with a different structure and a configuration to achieve the same function according to some other embodiments.

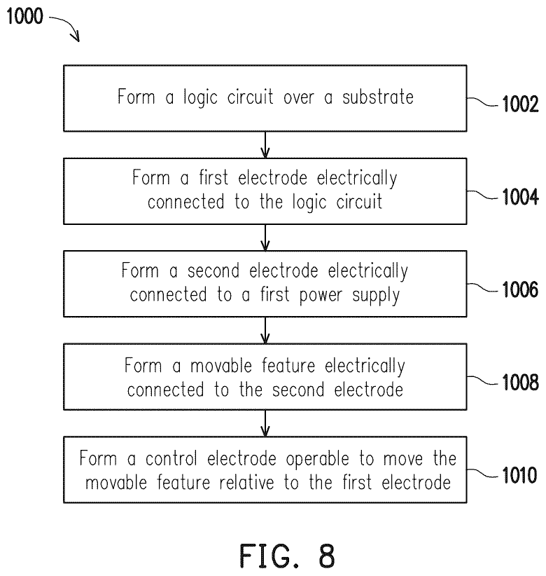

FIG. 8 illustrates a flowchart of a method 1000 to form a semiconductor structure 100 having a NEMS device 200 for power gating, according to an embodiment of the present disclosure. At operation 1002, the method 1000 forms a logic circuit over a substrate such as the logic circuit 300 and substrate 102 described herein. Forming the logic circuit may include forming various logic devices 300a having a channel region 104 between source/drain (S/D) epitaxial features 106, a gate structure 110 over the channel region 104, S/D contacts 112 over the S/D epitaxial features, and a gate contact 112 over the gate structure. The method 1000 then forms a nanoelectromechanical systems (NEMS) device 200 electrically connected to the logic circuit 300. The forming of the NEMS device 200 includes operations 1004 to 1010 to form various features of the NEMS device 200. At operation 1004, the method 1000 forms a first electrode (e.g., output electrode S) electrically connected to the logic circuit (or specifically to a source/drain feature of a logic device in the logic circuit). At operation 1006, the method 1000 forms a second electrode (e.g., input electrode D) electrically connected to a first power supply (e.g., VDD). At operation 1008, the method 1000 forms a movable feature (e.g., movable feature 208) electrically connected to the second electrode. And at operation 1010, the method 1000 forms a control electrode (e.g., control electrode G) operable to move the movable feature relative to the first electrode. As part of the method 1000, other features may also be formed such as various interconnect structures described herein.

The various NEMS devices 200 described herein may be formed by any suitable method that includes depositions, lithography processes, and etching processes. In some embodiments, these NEMS devices are first formed embedded in a dielectric material, such as in one or more interlayer dielectric (ILD) layers. Then, portions of the dielectric material surrounding the NEMS device 200 is etched away by a suitable process, thereby forming an air gap (e.g., air gap 250). As shown in the various figures, the air gaps 250 may expose various horizontal and/or vertical surfaces of the input electrode D, output electrode S, and control electrode G. Further, for purposes of illustration, for example, the method of forming the vertical NEMS device 200 includes forming the logic devices 300a and the vertical NEMS device structure, then removing the dielectric material around the vertical NEMS device structure. For purposes of illustration, for example, the method of forming the in-plane NEMS device 200 includes forming the logic devices 300a and one or more metal layers over the logic circuit (i.e., portion of the interconnect structure 300b), then performing a dual damascene process to form a trench over the one or more metal layers, then forming copper fill in the trench and perform CMP to form the in-plane NEMS device structure, then performing HF vapor etch to remove the dielectric surrounding the in-plane NEMS device structure.

Although not limiting, the present disclosure offers advantages for power gating logic devices. One example advantage is integrating the NEMS device in various BEOL locations to save device footprint in FEOL. Another example advantage is the mechanical nature of the NEMS device, thereby eliminating or significantly reducing leakage current. Another example advantage is the ease of integration and high CMOS logic compatibility, which allows for various types of NEMS devices such as cantilever NEMS devices, piezoelectric NEMS devices, vertical NEMS devices, in-plane NEMS devices, and comb structure NEMS devices. The various types of NEMS devices allow flexibility in design.

One aspect of the present disclosure pertains to a device. The device includes a substrate, a logic circuit disposed on the substrate, and a nanoelectromechanical systems (NEMS) device electrically connected to the logic circuit and formed on the substrate. The NEMS device includes a first electrode electrically connected to the logic circuit, a second electrode electrically connected to a first power supply, a movable feature electrically connected to the second electrode, and a control electrode operable to move the movable feature relative to the first electrode.

In an embodiment, the logic circuit includes logic devices over the substrate and an interconnect structure over the logic devices. Each of the logic devices includes a field effect transistor (FET) having a channel region between source/drain (S/D) epitaxial features, a gate structure over the channel region, S/D contacts over the S/D epitaxial features, and a gate contact over the gate structure. The interconnect structure includes metal lines and vias that electrically connect to one or more of the logic devices.

In a further embodiment, a first S/D epitaxial feature of the logic devices is electrically connected to the first electrode; and a second S/D epitaxial feature of the logic devices is electrically connected to a second power supply different from the first power supply.

In a further embodiment, the NEMS device is disposed above the logic devices and is embedded in or above the interconnect structure.

In a further embodiment, the NEMS device is disposed below the logic devices on a backside of the substrate.

In a further embodiment, the device further includes a second logic circuit over the logic circuit, where the second logic circuit includes second logic devices over a second substrate and a second interconnect structure over the second logic devices. The NEMS device is disposed above the second substrate.

In an embodiment, the movable feature lands on a horizontal surface of the first electrode. In an embodiment, each of the first electrode, the second electrode, the control electrode, and the movable feature includes Cu, W, Pt, Ru, Al, Co, TaN, TiN, or a combination thereof.

In a further embodiment, the movable feature further includes a piezoelectric layer electrically connected to the control electrode, a conductive layer electrically connected to the second electrode, and an insulator layer separating the piezoelectric layer from the conductive layer.

In an embodiment, a top surface of the first electrode is substantially coplanar with a top surface of the second electrode.

Another aspect of the present disclosure pertains to a device. The device includes a substrate, a logic circuit disposed on the substrate, and a nanoelectromechanical systems (NEMS) device formed on the substrate and electrically connected to the logic circuit. The NEMS device includes a first electrode electrically connected to the logic circuit, a second electrode electrically connected to a power supply VDD, a NEMS structure having a bendable end over the first electrode and a fixed end attached to the second electrode. The NEMS structure includes a piezoelectric layer. The NEMS device further includes a control electrode electrically connected to the NEMS structure. The control electrode and the piezoelectric layer are configured such that the bendable end is operable to bend and disconnect from the first electrode.

In an embodiment, the control electrode lands on a top surface of the fixed end of the NEMS structure.

In an embodiment, the NEMS structure further includes: a conducting metal layer, an insulator layer, a bottom piezoelectric electrode, and a top piezoelectric electrode, where the conducting metal layer is disposed on the second electrode, the insulator layer is disposed on the conducting metal layer, the bottom piezoelectric electrode is disposed on the insulator layer, the piezoelectric layer is disposed on the bottom piezoelectric electrode, and the top piezoelectric electrode is disposed on the piezoelectric layer. The control electrode is disposed on the top piezoelectric electrode.

In a further embodiment, the conducting metal layer includes Cu, W, Pt, Ru, Al, Co, TaN, TiN, or a combination thereof, the insulator layer includes SiO2, Si3N4, SiOC, SiCN, SION, SiCON, or a combination thereof, the bottom and top piezoelectric electrodes include Cu, W, Pt, Ru, Al, Co, TaN, TiN, or a combination thereof, and the piezoelectric layer includes BaTiO3, PbTiO3, Pb(ZrTi)O3, or a combination thereof.

In an embodiment, the NEMS structure has a length that ranges between 200 nm to 1000 nm and a thickness that ranges between 75 nm to 250 nm.

In an embodiment, the bendable end bends upwards such that the NEMS structure bends by a bending angle between about 5 degrees to about 15 degrees relative to a horizontal direction.

Another aspect of the present disclosure pertains to a method. The method includes forming a logic circuit over a substrate and forming a nanoelectromechanical systems (NEMS) device electrically connected to the logic circuit. The forming of the NEMS device includes forming a first electrode electrically connected to the logic circuit, forming a second electrode electrically connected to a first power supply, forming a movable feature electrically connected to the second electrode, and forming a control electrode operable to move the movable feature relative to the first electrode.

In an embodiment, the first electrode is electrically connected to a source/drain feature of a logic device in the logic circuit.

In an embodiment, the forming of the NEMS device includes forming the first electrode, the second electrode, the movable feature, and the control electrode in an interlayer dielectric (ILD) layer, and the method further includes etching a portion of the ILD layer surrounding the NEMS device to form an air gap surrounding the movable feature. In a further embodiment, the air gap exposes a horizontal surface of the first electrode.

The details of the method and device of the present disclosure are described in the attached drawings. The foregoing outlines features of several embodiments so that those of ordinary skill in the art may better understand the aspects of the present disclosure. Those of ordinary skill in the art should appreciate that they may readily use the present disclosure as a basis for designing or modifying other processes and structures for carrying out the same purposes and/or achieving the same advantages of the embodiments introduced herein. Those of ordinary skill in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
transistor devices in a device layer over a substrate, each transistor device having a channel region between source/drain (S/D) epitaxial features, a gate structure over the channel region, S/D contacts over the S/D epitaxial features, and a gate contact over the gate structure;
an interconnect structure over the device layer, wherein the interconnect structure includes metal lines and vias that electrically connect to the transistor devices; and
a nanoelectromechanical systems (NEMS) device over the interconnect structure and electrically connected to one or more of the transistor devices, the NEMS device comprises:
a first electrode electrically connected to the one or more transistor devices through the interconnect structure,
a second electrode electrically connected to a first power supply,
a movable feature electrically connected to the second electrode, and
a control electrode operable to move the movable feature relative to the first electrode by a second power supply.

2. The device of claim 1, wherein the NEMS device further comprises a dielectric layer embedding the first electrode, the second electrode, and the control electrode, wherein a top surface of the second electrode protrudes above a top surface of the dielectric layer.

3. The device of claim 1, wherein a top surface of the second electrode is above top surfaces of the first electrode and the control electrode, wherein the top surfaces of the first electrode and the control electrode are substantially coplanar.

4. The device of claim 1, wherein a bottom surface of the control electrode is above top surfaces of the first and the second electrodes, wherein the top surfaces of the first and the second electrodes are substantially coplanar.

5. The device of claim 1, wherein the movable feature lands on a top surface of the second electrode and is surrounded by an air gap.

6. The device of claim 5, wherein the movable feature further lands on a top surface of the first electrode.

7. The device of claim 1, wherein the interconnect structure include 8 to 13 metal lines between the NEMS device and the device layer.

8. The device of claim 1, wherein the NEMS device is formed in a passivation structure over the interconnect structure, and the passivation structure embeds an air gap surrounding the NEMS device.

9. The device of claim 1, wherein the transistor devices are first transistor devices and the interconnect structure is a first interconnect structure, further comprising:
a second substrate over the first interconnect structure;
second transistor devices over the second substrate; and
a second interconnect structure over the second transistor devices,
wherein the NEMS device is disposed over the second substrate and adjacent to the second transistor devices.

10. The device of claim 1, wherein each of the first electrode, the second electrode, the control electrode, and the movable feature includes Cu, W, Pt, Ru, Al, Co, TaN, TiN, or a combination thereof.

11. The device of claim 1, wherein the movable feature further includes a piezoelectric layer electrically connected to the control electrode, a conductive layer electrically connected to the second electrode, and an insulator layer separating the piezoelectric layer from the conductive layer.

12. A device, comprising:
transistor devices in a device layer over a substrate, each transistor device having a channel region between source/drain (S/D) epitaxial features, a gate structure over the channel region, S/D contacts over the S/D epitaxial features, and a gate contact over the gate structure;
an interconnect structure over the device layer, wherein the interconnect structure includes metal lines and vias that electrically connect to the transistor devices; and
a nanoelectromechanical systems (NEMS) device under the transistor devices on a backside of the substrate and electrically connected to one or more of the transistor devices, the NEMS device comprises:
a first electrode electrically connected to the one or more transistor devices through a backside via penetrating through the substrate,
a second electrode electrically connected to a first power supply,
a movable feature electrically connected to the second electrode, and
a control electrode operable to move the movable feature relative to the first electrode by a second power supply.

13. The device of claim 12, wherein the NEMS device further comprises a dielectric layer embedding the first electrode, the second electrode, and the control electrode, wherein a top surface of the second electrode protrudes below a bottom surface of the dielectric layer.

14. The device of claim 12, wherein a bottom surface of the second electrode is below bottom surfaces of the first electrode and the control electrode, wherein the bottom surfaces of the first electrode and the control electrode are substantially coplanar.

15. The device of claim 12, wherein a top surface of the control electrode is below bottom surfaces of the first and the second electrodes, wherein the bottom surfaces of the first and the second electrodes are substantially coplanar.

16. The device of claim 12, wherein the movable feature lands on a bottom surface of the second electrode and is surrounded by an air gap.

17. A device, comprising:
a substrate;
a logic circuit disposed on the substrate; and
a vertical nanoelectromechanical systems (NEMS) device on the substrate and electrically coupled to the logic circuit, the vertical NEMS device comprises:
a first electrode directly above and landing on a metal via of the logic circuit,
a second electrode adjacent the logic circuit and over the substrate, the second electrode is electrically connected to a power supply VDD,
a vertical metal beam landing on a top surface of the second electrode, and
a control electrode above the logic circuit and under the first electrode, wherein when the control electrode is applied with a control voltage, the vertical metal beam bends towards the control electrode until the vertical metal beam contacts the first electrode.

18. The device of claim 17,
wherein the first electrode is distanced away from the vertical metal beam by a separation distance, wherein the vertical metal beam bends at a bending angle such that a tangent of the bending angle is equal to a ratio of the separation distance to a height of the vertical metal beam, wherein the bending angle is between about 5 degrees to about 15 degrees relative to a vertical direction.

19. The device of claim 17, wherein the vertical metal beam has a height between 200 nm to 500 nm.

20. The device of claim 17, wherein the first electrode and the control electrode are embedded in an intermetal dielectric layer, and the vertical metal beam is surrounded by an air gap.
